(19) United States
(12) Patent Application Publication
(10) Pub. No.: US 2013/0307408 A1
(43) Pub. Date: Nov. 21, 2013

(54) LUMINOUS ARRAY FILM-TYPE DISPLAY DEVICE AND LUMINOUS ARRAY MULTIFILM-TYPE DISPLAY DEVICE

(71) Applicant: SHINODA PLASMA CO., LTD., Kobe-shi (JP)

(72) Inventors: Hitoshi HIRAKAWA, Kobe (JP); Koji Shinohe, Kobe (JP); Yukihoto Namekawa, Kobe (JP); Tetsuya Makino, Kobe (JP); Katsuhiko Itamasu, Kobe (JP)

(73) Assignee: Shinoda Plasma Co., Ltd., Kobe-shi (JP)

(21) Appl. No.: 13/866,553

(22) Filed: Apr. 19, 2013

(30) Foreign Application Priority Data
May 18, 2012 (JP) 2012-114272

(51) Int. Cl. H05K 7/06; H01J 17/49

(52) U.S. Cl. CPC H05K 7/06; H01J 17/492
USPC 313/584; 361/749

(57) ABSTRACT

A luminous array film-type display device having a multi-curved screen comprises, a luminous array film such as plasma tube array (PTA) and a support member supporting the luminous array film. The support member having a support surface that is curved continuously in one direction with at least two curvature radii supports the luminous array film along the curved surface.

### BACKGROUND OF THE INVENTION

1. Field of the Invention

The present invention relates to a luminous array film-type display device and a luminous array multifilm-type display device, each of which has a screen curved with a plurality of different curvature radii on one screen. Particularly, the present invention relates to a luminous array film-type display device and a luminous array multifilm-type display device, each of which has a screen that is configured with a plasma tube array with plasma tubes arranged in parallel and is curved with a plurality of different curvature radii on one screen.

2. Description of the Related Art

Several techniques for displaying images on screens with curved shapes have been developed as display devices of a new generation. Among them, an organic electroluminescence display or a plasma tube array (PTA) type display is known. Such display devices having large screens in the form of a film whose shape is changed easily also have been put to practical use.

For example, JP-B-3976604 (U.S. Pat. No. 6,914,382) discloses a plasma tube array (PTA)-type display device configured with a plurality of slender plasma tubes with a cross section of an oblate elliptical shape that are arranged in parallel between a flexible display electrode sheet and a flexible address electrode sheet. The plurality of slender plasma tubes each are filled with a discharge gas and are provided with a phosphor layer. In the PTA-type display device, it is possible to construct a supersized display screen easily by combining and connecting a plurality of units of display sub-modules together in matrix. The display sub-module has a screen size of 1 m square that is configured with 1000 plasma tubes arranged in parallel, each of which has a major axis of 1 mm and a length of 1 m.

On the other hand, in the fields of current advertising media and public display, electronic displays such as LCDs and PDPs are used widely, and besides the contents to be displayed, display devices themselves are required to have attractive designs appropriate to the installation environment. In this regard, since the PTA-type display device disclosed in JP-B-3976604 has flexibility that allows it to be curved in the direction in which the plasma tubes are arranged, it is possible to construct a highly attractive screen having various curved shapes such as a wavy shape and a ridge line shape in one display device. However, it is not economical to meet every single need of individual screen configurations, since this results in increases in design cost and production cost as well as production time.

Furthermore, when a screen with a curved shape is constructed, it is easy to specify the positions where a drive circuit and the like are to be placed if the curved shape has a constant curvature radius. However, when the curvature radius of the curved shape varies continuously on one screen, it is difficult to specify the positions where a drive circuit and the like are to be placed. In other words, since a circuit board has a flat-plate shape, the thickness of the display device might be increased depending on the positions where they are attached, or a wasted space might be produced on the rear side of the display screen.

### SUMMARY OF THE INVENTION

The present invention is intended to provide a luminous array film-type display device and a luminous array multifilm-type display device, in each of which a display device with a screen having a curved shape that meets a wide variety of needs can be assembled easily at a low cost and a circuit board commonized for each display device can be mounted reliably.

In order to achieve the above-mentioned object, a luminous array film-type display device according to a first invention comprises a support member having a support surface that is curved continuously in one direction with at least two curvature radii, wherein the support surface of the support member supports a flexible display film having a luminous point array, and a plate-shaped chassis, on which a circuit board is mounted, is fixed to the opposite surface of the support surface.

A luminous array film-type display device according to a second invention is characterized by, in the first invention, comprising a gap between the support member and the plate-shaped chassis, with the space size of the gap varying partially along the one direction.

A luminous array film-type display device according to a third invention is characterized in that, in the first or second invention, the display film has a structure in which a plurality of plasma tubes arranged in parallel are held between an address electrode sheet and a display electrode sheet, and the display film is flexible in a direction in which the plasma tubes are arranged, and the plasma tube array is supported by the support surface of the support member in such a manner that the direction in which the plasma tubes are arranged coincides with the one direction of the curved support member.

Next, in order to achieve the above-mentioned object, a luminous array multifilm-type display device according to a fourth invention is configured with a pair of luminous array film-type display devices according to any one of the first to third inventions that are connected together at a predetermined angle, wherein display surfaces of the pair of luminous array film-type display devices connected together are configured to have line symmetry about a connected portion thereof.

A luminous array multifilm-type display device according to a fifth invention is characterized in that, in the fourth invention, the pair of luminous array film-type display devices are supported by a connecting frame body formed of right and left supporting frames combined together that are bent in a dogleg shape at a predetermined angle.

A luminous array multifilm-type display device according to a sixth invention is characterized in that, in the fourth invention, the pair of luminous array film-type display devices are connected together rotatably about a connecting mechanism.

The luminous array film-type display device according to the present invention comprises a support member having a support surface that is curved continuously in one direction with at least two curvature radii, wherein the support surface of the support member supports a flexible display film having a luminous point array, and a plate-shaped chassis, on which a circuit board is mounted, is fixed to the opposite surface of the support surface. Therefore, screens with various curved surfaces that meet individual needs can be obtained and a circuit board can be commonized by being mounted on a plate-shaped chassis provided separately from the support member that supports the display film. Accordingly, a luminous array film-type display device with a screen having a curved shape and a luminous array multifilm-type display device configured with a plurality of the luminous array film-type display devices connected together can be assembled easily at a low cost.

### BRIEF DESCRIPTION OF THE DRAWINGS

FIGS. 1A and 1B are perspective views showing the outer structure of a luminous array multifilm-type display device according to an embodiment of the present invention.

FIG. 2 is an exploded perspective view showing the parts structure of the luminous array multifilm-type display device according to the embodiment of the present invention, viewed from the rear side thereof.

FIG. 3 is a transverse sectional view that schematically shows an example of the shape of a support surface of a support member of the luminous array film-type display device according to the embodiment of the present invention.

FIGS. 4A and 4B are perspective views that schematically show the structure of a display film obtained when a PTA is used of a luminous array film-type display device according to the embodiment of the present invention.

FIG. 5 is a cross-sectional view showing the structure obtained when a PTA is used for the display film of the luminous array film-type display device according to the embodiment of the present invention.

FIG. 6 is a rear view showing the general outline of the luminous array multifilm-type display device according to the embodiment of the present invention.

FIG. 7 is a perspective view showing the structure, which is obtained when a pair of luminous array film-type display devices are rotatably connected together, of the luminous array multifilm-type display device according to the embodiment of the present invention.

FIG. 8 is a schematic cross-sectional view showing a gap in the luminous array film-type display device according to the embodiment of the present invention.

### BEST MODE FOR CARRYING OUT THE INVENTION

Hereinafter, a display device according to an embodiment of the present invention is described in details with reference to the drawings.

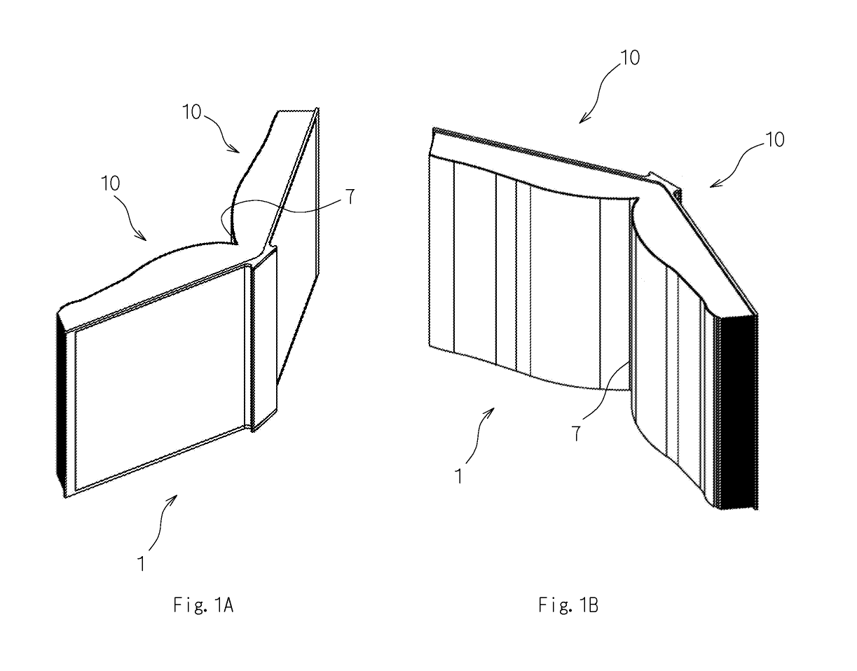

FIGS. 1A and 1B are perspective views showing the outer structure of a luminous array multifilm-type display device according to an embodiment of the present invention. FIG. 1A is a perspective view of the luminous array multifilm-type display device according to the present embodiment, viewed from the rear side thereof. FIG. 1B is a perspective view of the luminous array multifilm-type display device according to the present embodiment, viewed from the display surface side (the front side) thereof. The display surface of the embodiment shown in FIGS. 1A and 1B looks like an opened book style.

As shown in FIGS. 1A and 1B, a luminous array multifilm-type display device 1 according to the present embodiment is configured with a pair of luminous array film-type display devices 10, 10, which have curved display surfaces, connected together. The “luminous array film-type display device” denotes a display device that is configured with a film-like display device (hereinafter referred to as a “display film”) as a main component and that comprises a drive circuit, a power supply circuit, etc., individually. The “luminous array multifilm-type display device” denotes a display device comprising a plurality of luminous array film-type display devices 10 connected together, with each of the devices 10 comprising a drive circuit, a power supply circuit, etc., individually.

Furthermore, the display film is not particularly limited as long as it allows a curved shape to be obtained. For example, it may be a display film composed of organic electroluminescence or a display film composed of a PTA (a plasma tube array) described later. It is convenient to configure the luminous array film-type display device 10 with a flexible display film, for example, composed of a PTA.

Preferably, the display surfaces of the pair of luminous array film-type display devices 10, 10 that are connected together have line symmetry about the connected portion thereof. This is because such a configuration tends not to cause a sense of uncomfortableness to images displayed as an opened book style. However, the display surfaces need not to have line symmetry depending on the images to be displayed and can be designed flexibly depending on the intended use.

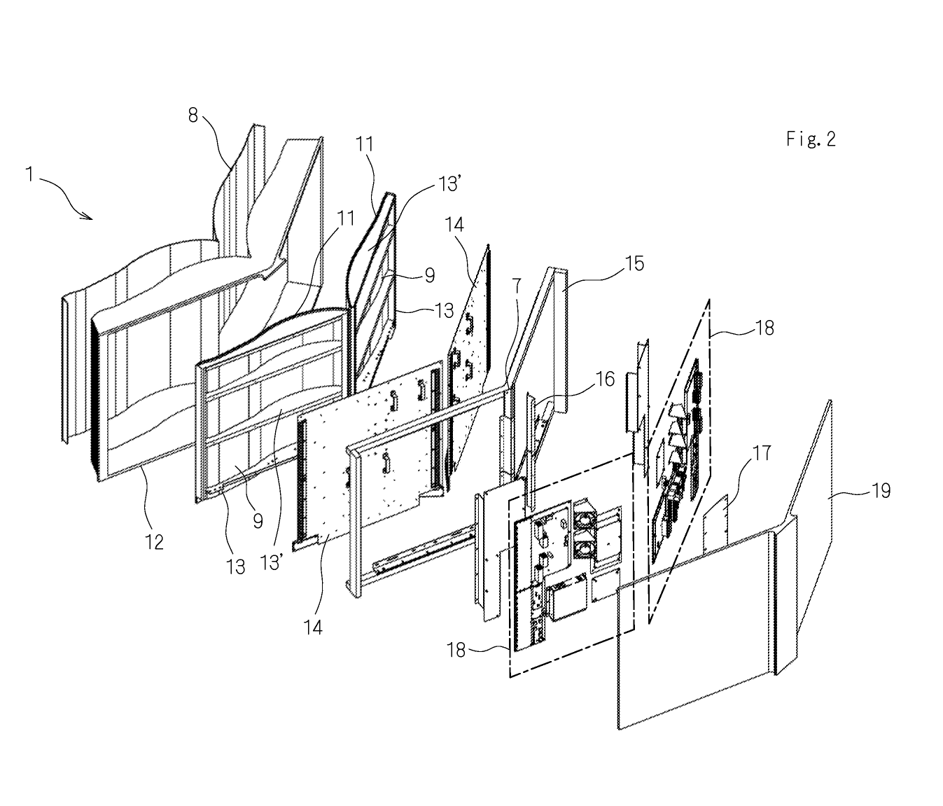

FIG. 2 is an exploded perspective view showing the parts structure of the luminous array multifilm-type display device 1 according to the embodiment of the present invention, viewed from the rear side thereof. As shown in FIG. 2, a pair of display films 11, 11 are attached individually to support surfaces of a pair of support members (face plates) 13, 13 to be supported thereby. The support surfaces each are continuously curved in one direction with at least two curvature radii. The pair of support members 13, 13 can be fitted in a frame-like outer cover 12 together with the display films 11, 11, and a transparent front cover 8 is provided on the front surfaces thereof. The transparent front cover 8 has a curved surface along the shapes of the display films 11, 11 and is made of, for example, acrylic resin. Like a display film composed of a PTA described later, a flexible display film having a luminous array with light-emitting points arranged vertically and horizontally in matrix is used for the display film 11 of the luminous array film-type display device 10. In the example of FIG. 2, the display films 11 are supported by the support surfaces of the pair of support members 13, 13 curved to form a surface curved continuously in the transverse direction of the screen, respectively.

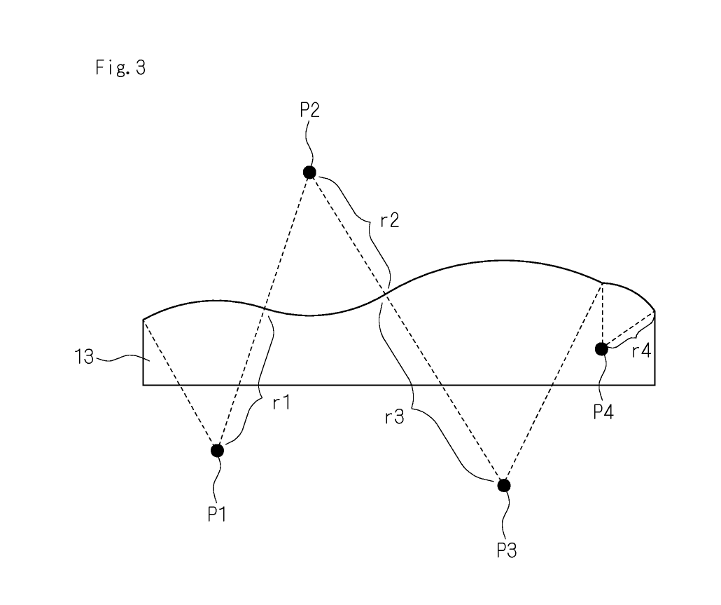

FIG. 3 is a transverse sectional view that schematically shows an example of the shape of the support surface of a support member (a face plate) 13 of the luminous array film-type display device 1 according to the embodiment of the present invention. In the example of FIG. 3, the support surface of the support member 13 is curved in the transverse direction in the screen with four curvature radii r1, r2, r3, and r4 (with centers of curvature P1, P2, P3, and P4, respectively). In this manner, the support member 13 has a support surface that is not of a simple concave or convex shape but of a shape formed with concave and convex shapes combined together.

With reference to FIG. 2 again, a plurality of ribs 13′, 13′, . . . for reinforcement are fixed to the opposite surfaces of the support surfaces of the pair of support members 13, 13 in the curved direction and furthermore, plate-shaped chassis 14, 14 that allow circuit boards 18 to be mounted thereon are fixed to the opposite surfaces to the support surfaces of the pair of support members 13, 13 in such a manner as to hold a plurality of the ribs 13′, 13′, . . . therebetween, respectively. On each of a pair of the plate-shaped chassis 14, 14, a circuit board 18 equipped with electronic components such as a drive circuit, a power supply circuit, etc. is mounted.

The pair of plate-shaped chassis 14, 14 with the circuit boards 18 mounted thereon are combined with the pair of support members 13, 13 that support the pair of display films 11, 11, respectively, to construct the pair of luminous array film-type display devices 10, 10 or display sub-modules that are parts of the display device. They are fitted into a connecting frame body 15 to be incorporated into the outer cover 12. The rear side of the connecting frame body 15 is covered with a back cover 19 that covers the rear side of the outer cover 12. Ground potential connection covers 16, 17 are provided as ground electrodes between the connecting frame body 15 and the back cover 19. Furthermore, a gap 9 whose space size varies partially along the curved surface of each support member 13 is provided between the support member 13 and the plate-shaped chassis 14.

Moreover, the display films 11 each are composed of, for example, a plasma tube array (hereinafter referred to as a “PTA”) including a plurality of plasma tubes filled with a discharge gas that are arranged in parallel. Accordingly, no large-scale equipment is required to handle large glass substrates that are necessary in manufacturing large-sized display panels such as LCDs and PDPs. In addition, since the display films 11 each are formed as a flexible film, it is possible to construct, at a low cost, a screen with a curved shape that can perform natural image display.

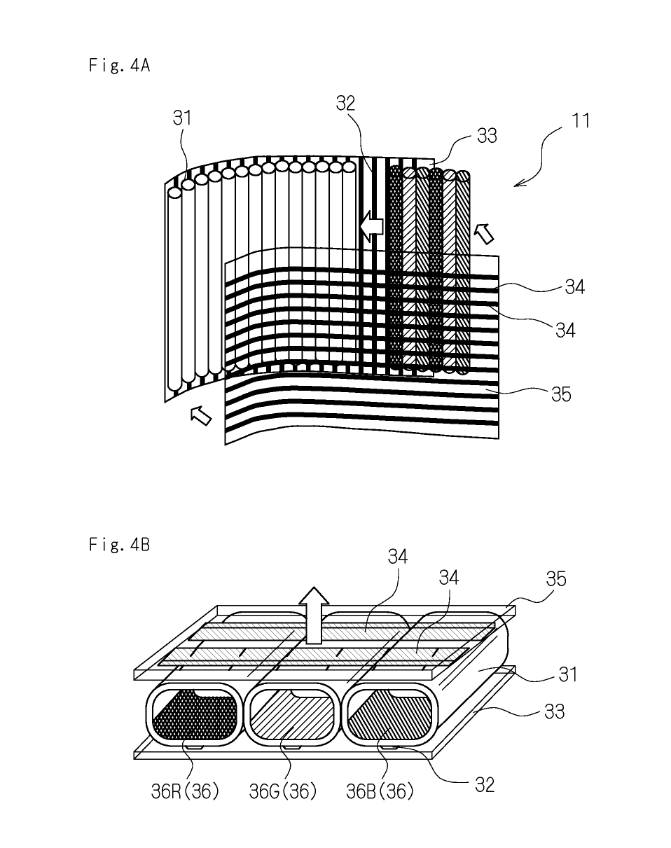

FIG. 4A is a perspective view that schematically shows the structure of the display film 11 composed of the PTA of the luminous array film-type display device 10 according to the present embodiment. FIG. 4B is a perspective view that shows a part of the structure of the display film 11 composed of the PTA of the luminous array film-type display device 10 according to the present embodiment.

As shown in FIG. 4A, a plurality of plasma tubes 31, 31, . . . filled with a discharge gas are arranged in parallel. The plasma tubes 31, 31, . . . are discharging thin tubes made of glass. The diameter of each thin tube to serve as a tube body is not particularly limited. Desirably, however, the diameter is approximately 0.5 to 5 mm. The cross-sectional shape of the thin tube can be any shape such as a circular shape, a flattened elliptical shape, or a rectangular shape. Furthermore, the plasma tubes 31, 31, . . . are filled with a discharge gas such as neon, xenon and the like at a predetermined ratio and a predetermined pressure.

A plurality of the plasma tubes 31, 31, . . . arranged in parallel are held between an address electrode sheet 33 located on the rear side and a display electrode sheet 35 located on the display surface side. The address electrode sheet 33 comprises address electrodes 32, 32, . . . that are arranged in the longitudinal direction of the plasma tubes 31, 31, . . . in such a manner as to be in contact with the lower surfaces of the respective plasma tubes 31. The display electrode sheet 35 comprises display electrodes 34, 34, . . . that are arranged in the direction intersecting the longitudinal direction of the plasma tubes 31, 31, . . . in such a manner as to be in contact with the upper surfaces of the respective plasma tubes 31. The display electrode sheet 35 is a flexible sheet and is formed of, for example, a polycarbonate film or a polyethylene terephthalate (PET) film.

A plurality of the display electrodes 34, 34, . . . are arranged in a stripe pattern on the inner surface of the display electrode sheet 35 and are in contact with the upper surfaces of the respective plasma tubes 31. Adjacent display electrodes 34, 34 composing a display electrode pair function as an X electrode and a Y electrode. A display discharge is generated in the plasma tubes 31, 31, . . . between the X electrode and the Y electrode. Besides the stripe pattern, the pattern of the display electrodes 34 can be any pattern known in the present field such as a mesh pattern, a ladder pattern, or a comb-shape pattern. Examples of the materials that are used for the display electrodes 34 include transparent conductive materials such as indium tin oxide (ITO) and SnO₂ as well as metal conductive materials such as Ag, Au, Al, Cu, and Cr.

Various methods known in the present field can be used for the method of forming the display electrodes 34. For example, they may be formed using a thick-film forming technique such as printing or may be formed using a technique of patterning with photolithography and a thin-film forming technique that includes a physical deposition method or a chemical deposition method. Examples of the thick-film forming technique include a screen printing method. Among thin-film forming techniques, examples of the physical deposition method include a vapor deposition method and a sputtering method, while examples of the chemical deposition method include a thermal CVD method, a photo-CVD method, and a plasma CVD method.

The address electrodes 32, 32, . . . each are provided per plasma tube 31 on the rear faces of a plurality of the plasma tubes 31, 31, . . . arranged in parallel along the longitudinal direction of the plasma tubes 31, 31, . . . . The address electrodes 32, 32, . . . form light-emitting cells at intersections with the paired display electrodes 34, 34, . . . . The address electrodes 32 also can be formed using various materials and methods that are known in the present field. The address electrode sheet 33 with the address electrodes 32, 32, . . . formed thereon is shown as one sheet for convenience sake but actually it is divided into a plurality of sheets per, for example, a set of three plasma tubes 31 for three colors RGB or 8 sets of 24 plasma tubes 31 of three plasma tubes 31 for three colors RGB from the viewpoints that the position errors caused between the plasma tubes 31 and the address electrodes 32 due to minute differences in diameter size of respective plasma tubes 31 are absorbed and that the display screen is provided with flexibility in the direction intersecting the longitudinal direction of the plasma tubes 31, 31, . . . .

In the above-described configuration, when the display device serves as one for color display, as shown in FIG. 4B, each plasma tube 31 comprises a red (R) phosphor layer 36R, a green (G) phosphor layer 36G, or a blue (B) phosphor layer 36B. When one pixel is configured with one set of plasma tubes 31, 31, and 31 of three colors RGB, the display device can serve as one for color display. In the case of the red (R) phosphor layer 36R, a phosphor material such as (Y, Gd)BO₃:Eu³+ that emits red light by ultraviolet irradiation is used for the phosphor layer 36. In the case of the green (G) phosphor layer 36G, a phosphor material such as Zn₂SiO₄:Mn that emits green light is used, while in the case of the blue (B) phosphor layer 36B, a phosphor material such as BaMgAl₁₂O₁₇:Eu²⁺ that emits blue light is used.

When the display film 11 composed of the PTA having the above-described structure is used, the luminous array film-type display device 10 according to the present embodiment has a display surface with a curved shape formed with a plurality of curvature radii in the direction in which the plasma tubes are arranged (the direction intersecting the longitudinal direction of the plasma tubes). Furthermore, in the case of a multiscreen structure, although in FIGS. 1 and 2, the pair of luminous array film-type display devices 10, 10 are connected together at a predetermined angle and the display surfaces of the pair of luminous array film-type display devices 10, 10 have line symmetry about the connected portion thereof, they are not particularly limited thereto.

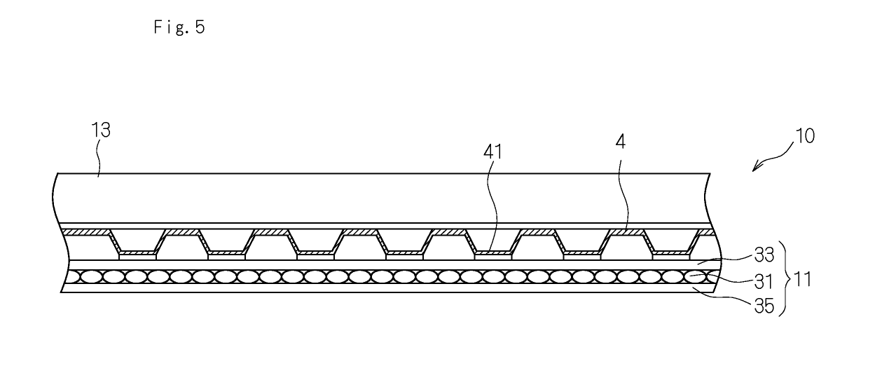

FIG. 5 is a cross-sectional view showing the structure obtained when a PTA is used for the display film 11 of the luminous array film-type display device 10 according to the embodiment of the present invention. In FIG. 5, the display surface is shown to have a planar shape for easy description.

As shown in FIG. 5, the luminous array film-type display device 10 using PTA-type display film 11 comprises the support member 13 and an intermediate sheet 4. The display film 11 comprises a plurality of plasma tubes 31, 31, . . . filled with a discharge gas that are arranged in parallel. The display film 11 holds a plurality of the plasma tubes 31, 31, . . . between the address electrode sheet 33 located on the rear side and the display electrode sheet 35 located on the display surface side. The address electrode sheet 33 is provided with the address electrodes 32, 32, . . . formed thereon. The display electrode sheet 35 is provided with the display electrodes 34, 34, . . . formed thereon. The support member 13 supports the rear side of the display film 11 and defines the shape of the display surface. The intermediate sheet 4 has flexibility and attaches the rear side of the display film 11 and the support member 13 together.

The support member 13 is a substrate to be attached to the display film 11 composed of the PTA. The substrate is formed using aluminum, carbon reinforced resin, etc. The support member 13 has a function of defining the shape of the display surface of the display film 11 composed of the flexible PTA.

The rear side of the display film 11 composed of the PTA is attached to the support member 13, with the flexible intermediate sheet 4 being interposed therebetween. Therefore, in the case that the support surface of the support member 13 to be attached to the rear side of the PTA film (the display film composed of the PTA) 11 has irregularities caused due to distortion, damages, or uneven application of an adhesive, the intermediate sheet 4 can prevent the PTA film 11 from being distorted by the irregularities caused on the support surface of the support member 13. Therefore, even when the surface of the support member 13 to be attached to the rear side of the PTA film 11 has a low precision or is rough, the quality of display devices is secured high.

The intermediate sheet (buffer sheet) 4 is formed using, for example, thin silicon resin with a hardness of 12 or less, preferably a hardness of approximately 8 to 5, so as to have flexibility. Furthermore, the intermediate sheet 4 has a plurality of convex parts 41 on the surface thereof to be attached to the address electrode sheet 33 of the PTA film 11 (the rear side of the PTA film 11). The rear side of the PTA film 11 is not directly attached to the support member 13 but is attached to the support member 13, with the intermediate sheet 4, having a plurality of the convex parts 41 on the surface thereof to be attached to the address electrode sheet 33 of the PTA film 11, being interposed therebetween. Therefore, the PTA film 11 can be removed from the support member 13 easily.

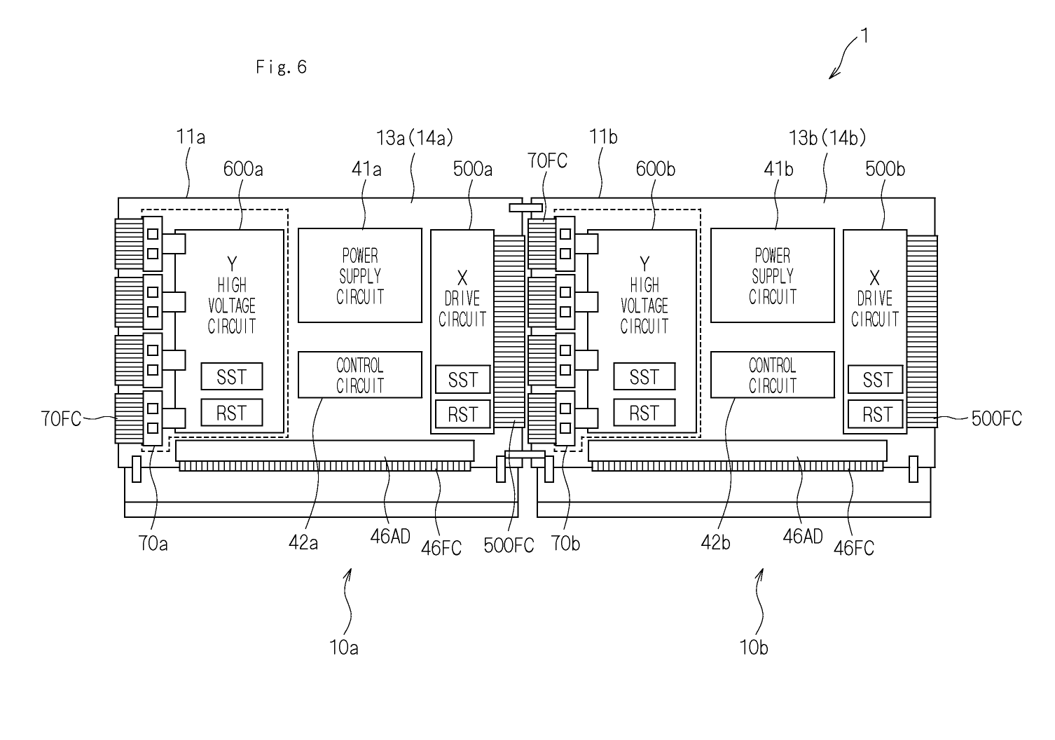

FIG. 6 is a rear view showing the general outline of the luminous array multifilm-type display device 1 according to the embodiment of the present invention. In the present embodiment, a pair of luminous array film-type display devices 10a, 10b each have a drive circuit that can be driven independently.

As shown in FIG. 6, in the present embodiment, the luminous array multifilm-type display device 1 having a display screen curved over the whole is configured with the pair of luminous array film-type display devices 10a, 10b connected together at a predetermined angle. The pair of luminous array film-type display devices (PTA film displays) 10a, 10b have, as basic components thereof, a pair of display films 11a, 11b, each of which is composed of the PTA of, for example, 1 m square, and is equipped with various circuits required for individual screen display on the rear sides of a pair of support members 13a, 13b having curved support surfaces that support the display films 11a, 11b, respectively. Specifically, a pair of plate-shaped chassis 14a, 14b are fixed to the opposite surfaces of the support surfaces of the pair of support members 13a, 13b, and X drive circuit boards 500a, 500b and Y drive circuit boards 70a, 70b as drive circuit boards, Y high voltage circuit boards 600a, 600b, power supply circuit boards 41a, 41b, and control circuit boards 42a, 42b are mounted on the pair of plate-shaped chassis 14a, 14b, respectively.

Among display electrode pairs of the pair of PTA film display 10a, 10b, X electrode groups are bent towards the rear side with flexible cables 500FC along the side surfaces of the plasma tubes arranged at the rightmost ends of the pair of display films 11a, 11b composed of the PTAs to be connected to the X drive circuit boards 500a, 500b. Among the display electrode pairs of the pair of PTA film display 10a, 10b, Y electrode groups also are bent towards the rear side with flexible cables 70FC along the side surfaces of the plasma tubes arranged at the leftmost ends of the display films 11a, 11b composed of the PTAs to be connected to the Y drive circuit boards 70a, 70b. Furthermore, address electrode groups are connected to address drive circuit boards 46AD using flexible cables 46FC.

As shown in FIGS. 1 and 2, the pair of luminous array film-type display devices 10, 10 of the display device 1 are supported by the connecting frame body 15 formed of right and left supporting frames combined together that are bent in a dogleg shape at a predetermined angle. However, this is not particularly limited thereto. For example, the pair of luminous array film-type display devices 10, 10 may be connected together rotatably about a connecting mechanism such as a hinge structure.

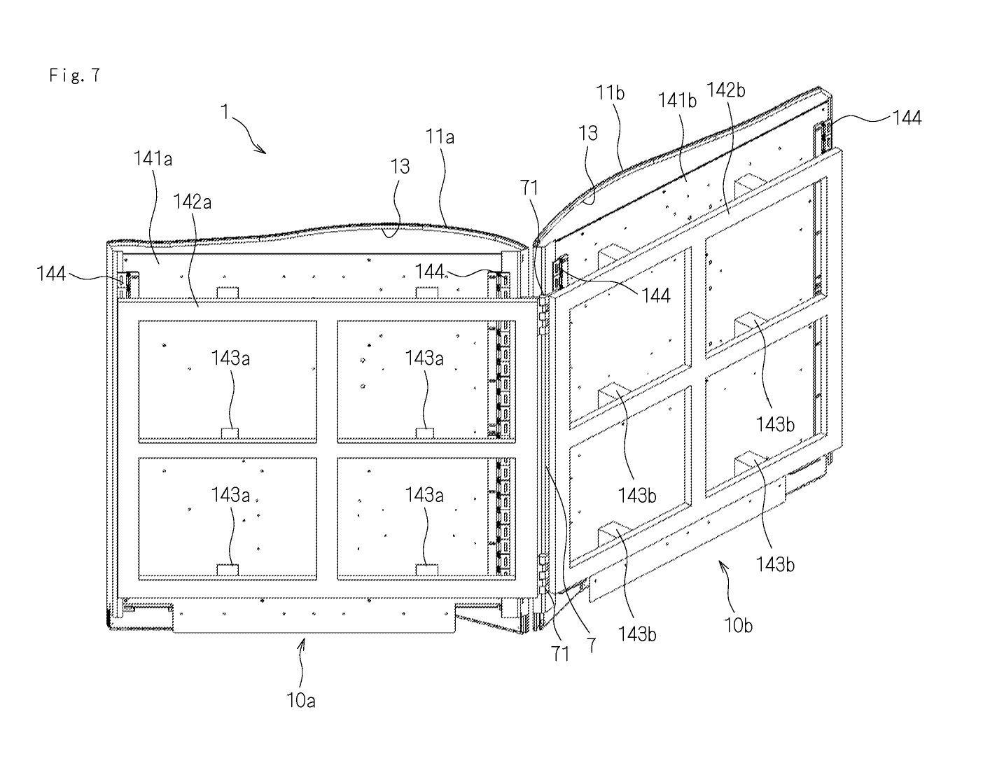

FIG. 7 is a perspective view showing the structure, which is obtained when the pair of luminous array film-type display devices 10a, 10b are rotatably connected together, of the display device 1 according to the embodiment of the present invention. The pair of luminous array film-type display devices 10a, 10b are configured with the pair of PTA films 11a, 11b that are supported by the support surfaces of the pair of support frames 13a, 13b having curved support surfaces, respectively.

Each plate-shaped chassis 14 has a double structure composed of a main chassis 141 and a sub-chassis 142. A pair of main chassis 141a, 141b are fixed to the opposite surfaces of the support surfaces of the pair of support frames 13, 13. A pair of sub-chassis 142a, 142b are fixed to the pair of main chassis 141a, 141b, with support posts 143a, 143b being interposed therebetween. As well as the pair of main chassis 141a, 141b, the pair of sub-chassis 142a, 142b are formed of thin plates made of metal such as aluminum. In order to reduce the weight thereof as much as possible, it is preferable that they each have a window frame shape with a plurality of holes.

Display electrode sheets (not shown in the drawings) located on the display surface side of the pair of display films 11, 11 composed of the PTAs are bent towards the rear side to be connected to connectors 144, 144 located at both ends of each of the pair of main chassis 141a, 141b. With, for example, flexible cables that are not shown in the drawings, the connectors 144, 144 are connected to the circuit boards 18 mounted on the pair of sub-chassis 142a, 142b.

The pair of the sub-chassis 142a, 142b are connected together with hinges 71, 71 that function as a connecting mechanism. With this structure, the pair of the main chassis 141a, 141b, to which the pairs of the sub-chassis 142a, 142b are fixed, the pair of the support frames 13, 13, and in turn the pair of the display films 11a, 11b supported by the pair of the support frames 13, 13 can be rotatable about the hinges 71, 71. Thus the angle at which the pair of the luminous array film-type display devices 10a, 10b are connected together can be freely adjusted.

In the example of FIG. 7, the hinges 71 are provided in two places on the upper and lower sides. However, the number of the hinges is not particularly limited as long as it allows certain connection strength to be maintained. Furthermore, the structure of the plate-shaped chassis 14 is not limited to the double structure composed of the main chassis 141 and the sub-chassis 142 as long as the pair of the luminous array film-type display devices 10a, 10b can be connected together rotatably about the connecting mechanism.

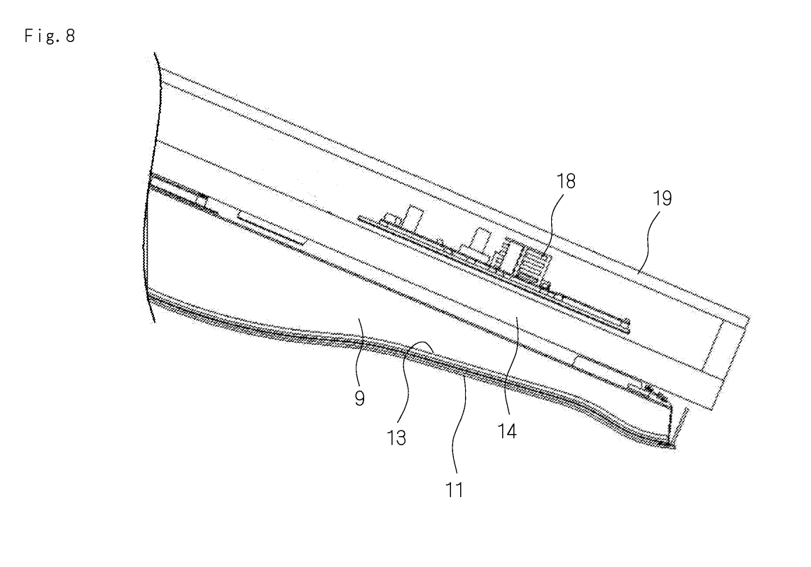

Since the circuit board 18 mounted on the plate-shaped chassis 14 tends to generate heat, it is preferable that a ventilation mechanism for circulating air is provided. FIG. 8 is a schematic cross-sectional view showing a gap of the luminous array film-type display device 10 according to the embodiment of the present invention.

As shown in FIG. 8, since the circuit board 18 mounted on the plate-shaped chassis 14 tends to generate heat, for example, a fan that is not shown in the drawings may be provided as a ventilation mechanism for circulating air in the gap 9 formed between the support surface of the support member 13 and the plate-shaped chassis 14. Preferably, the fan is installed at a fixed inclination angle because of the following reason. That is, since the gap 9 has space sizes that partially vary along the transverse direction of the screen (one direction) between the curved support member 13 and the plate-shaped chassis 14 and thereby the air (gas) flow tends to be disturbed inside the gap 9, the amount of the air blown against the plate-shaped chassis 14 with the circuit board 18 mounted thereon can be increased, which allows the effect of cooling the circuit board 18 to be improved.

Preferably, the fan is provided at an end of the gap 9 because of the following reason. That is, by generating air flow in the curved direction, the strength of the air flow varies depending on the space sizes and thereby both the display film 11 and electronic components mounted on the circuit board 18 can be cooled effectively through the support member 13 and the chassis 14. Furthermore, by selecting, depending on the space size, the position where the electronic components supposed to generate heat are mounted, the cooling effect can be improved further. Moreover, the cooling effect can also be improved by mounting a part of electronic components supposed to generate heat on the surface of the plate-shaped chassis 14 opposing the support member 13. It should be understood that when air flow is generated in the gap 9, an air inlet and an air outlet are provided suitably for portions of the outer cover 12 and the back cover 19.

As described above, according to the present embodiment, a support member 13 having a support surface that is curved continuously in one direction with at least two curvature radii is provided, the support surface of the support member 13 supports the flexible display film 11 with a luminous array, and the plate-shaped chassis 14 on which the circuit board 18 can be mounted is fixed to the opposite surface of the support surface. Therefore, screens with various curved surfaces that meet individual needs can be obtained and the circuit board 18 can be mounted on the plate-shaped chassis 14 to be commonized, with the plate-shaped chassis 14 provided separately from the support member 13 that supports the display film 11. Accordingly, the luminous array film-type display device 10 with a screen having a curved shape and the luminous array multifilm-type display device 1 configured with a plurality of the luminous array film-type display devices 10 connected together can be assembled easily at a low cost.

The present invention is not limited to the embodiment described above as long as it does not depart from the spirit thereof. The present invention can be subjected to various alterations, replacements, etc. For example, the circuit board 18 can be provided on the gap 9 side. In this case, electronic components that generate heat can be cooled directly by air flow.

The invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

What is claimed is:

1. A luminous array film-type display device, comprising a support member having a support surface that is curved continuously in one direction with at least two curvature radii,
wherein the support surface of the support member supports a flexible display film having a luminous point array, and a plate-shaped chassis, on which a circuit board is mounted, is fixed to the opposite surface of the support surface.

2. The luminous array film-type display device according to claim 1, comprising a gap between the support member and the plate-shaped chassis, with the space size of the gap varying partially along the one direction.

3. The luminous array film-type display device according to claim 1, wherein the display film has a structure in which a plurality of plasma tubes arranged in parallel are held between an address electrode sheet and a display electrode sheet, and the display film is flexible in a direction in which the plasma tubes are arranged, and
the plasma tube array is supported by the support surface of the support member in such a manner that the direction in which the plasma tubes are arranged coincides with the one direction of the curved support member.

4. The luminous array film-type display device according to claim 2, wherein the display film has a structure in which a plurality of plasma tubes arranged in parallel are held between an address electrode sheet and a display electrode sheet, and the display film is flexible in a direction in which the plasma tubes are arranged, and
the plasma tube array is supported by the support surface of the support member in such a manner that the direction in which the plasma tubes are arranged coincides with the one direction of the curved support member.

5. A luminous array multifilm-type display device, which is configured with a pair of luminous array film-type display devices according to claim 1 that are connected together at a predetermined angle,
wherein display surfaces of the pair of luminous array film-type display devices connected together are configured to have line symmetry about a connected portion thereof.

6. A luminous array multifilm-type display device, which is configured with a pair of luminous array film-type display devices according to claim 2 that are connected together at a predetermined angle,
wherein display surfaces of the pair of luminous array film-type display devices connected together are configured to have line symmetry about a connected portion thereof.

7. A luminous array multifilm-type display device, which is configured with a pair of luminous array film-type display devices according to claim 3 that are connected together at a predetermined angle,
wherein display surfaces of the pair of luminous array film-type display devices connected together are configured to have line symmetry about a connected portion thereof.

8. A luminous array multifilm-type display device, which is configured with a pair of luminous array film-type display devices according to claim 4 that are connected together at a predetermined angle,
wherein display surfaces of the pair of luminous array film-type display devices connected together are configured to have line symmetry about a connected portion thereof.

9. The luminous array multifilm-type display device according to claim 5, wherein the pair of luminous array film-type display devices are supported by a connecting frame body formed of right and left supporting frames combined together that are bent in a dogleg shape at a predetermined angle.

10. The luminous array multifilm-type display device according to claim 6, wherein the pair of luminous array film-type display devices are supported by a connecting frame body formed of right and left supporting frames combined together that are bent in a dogleg shape at a predetermined angle.

11. The luminous array multifilm-type display device according to claim 7, wherein the pair of luminous array film-type display devices are supported by a connecting frame body formed of right and left supporting frames combined together that are bent in a dogleg shape at a predetermined angle.

12. The luminous array multifilm-type display device according to claim 8, wherein the pair of luminous array film-type display devices are supported by a connecting frame body formed of right and left supporting frames combined together that are bent in a dogleg shape at a predetermined angle.

13. The luminous array multifilm-type display device according to claim 5, wherein the pair of luminous array film-type display devices are connected together rotatably about a connecting mechanism.

14. The luminous array multifilm-type display device according to claim 6, wherein the pair of luminous array film-type display devices are connected together rotatably about a connecting mechanism.

15. The luminous array multifilm-type display device according to claim 7, wherein the pair of luminous array film-type display devices are connected together rotatably about a connecting mechanism.

16. The luminous array multifilm-type display device according to claim 8, wherein the pair of luminous array film-type display devices are connected together rotatably about a connecting mechanism.
